(19) United States
(12) Patent Application Publication
(10) Pub. No.: US 2024/0021566 A1
(43) Pub. Date: Jan. 18, 2024

(54) Semiconductor Device and Method of Forming Underfill Dam for Chip-to-Wafer Device

(71) Applicant: STATS ChipPAC Pte. Ltd., Singapore (SG)

(72) Inventors: WooSoon Kim, Incheon (KR); JoonYoung Choi, Incheon (KR); YoungCheol Kim, Gyeonggi-do (KR); KyungOe Kim, Incheon (KR)

(73) Assignee: STATS ChipPAC Pte. Ltd., Singapore (SG)

(21) Appl. No.: 17/812,836

(22) Filed: Jul. 15, 2022

(51) Int. Cl. H01L 23/00; H01L 25/16; H01L 21/56

(52) U.S. Cl. CPC H01L 24/32; H01L 24/94; H01L 24/97; H01L 24/16; H01L 24/73; H01L 25/167; H01L 24/27; H01L 21/563; H01L 2924/12043; H01L 2924/13056; H01L 2924/15311; H01L 2924/182; G02B 6/13

(57) ABSTRACT

A semiconductor device has a semiconductor die with a sensitive area. A dam wall is formed over the semiconductor die proximate to the sensitive area. In one embodiment, the dam wall has a vertical segment and side wings. The dam wall can have a plurality of rounded segments integrated with a plurality of vertical segments as a unitary body. Alternatively, the dam wall has a plurality of separate vertical segments arranged in two or more overlapping rows. A plurality of conductive posts is formed over the semiconductor die. An electrical component is disposed over the semiconductor die. The semiconductor die and electrical component are disposed over a substrate. An insulating layer is formed over the substrate outside the dam wall. An underfill material is deposited between the semiconductor die and substrate. The dam wall and insulating layer inhibit the underfill material from contacting any portion of the sensitive area.

### FIELD OF THE INVENTION

The present invention relates in general to semiconductor devices and, more particularly, to a semiconductor device and method of forming an underfill dam for chip-to-wafer (C2 W) device.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain one or more semiconductor die and integrated passive devices (IPDs) to perform necessary electrical functions. In one example, a C2 W device typically starts with an active semiconductor wafer containing many of a first type of semiconductor die. The first type semiconductor die includes a sensitive area, such as a waveguide, sensor, optical, or photonic region, generally at a perimeter of the die. A plurality of conductive pillars is formed on an active surface of the first semiconductor die. A second type of semiconductor die is singulated from its wafer and mounted to the active surface of the first semiconductor wafer between the conductive pillars. The first semiconductor die, with conductive pillars and second semiconductor die, are singulated and mounted to an interconnect substrate. An underfill material is deposited between the first semiconductor die and interconnect substrate, around the conductive pillars and second semiconductor die, for isolation and environmental protection. The sensitive area of the first semiconductor die should be protected from the underfill material to avoid contaminating or covering the sensitive area, causing reliability issues, defects, and failures.

### BRIEF DESCRIPTION OF THE DRAWINGS

FIGS. 1a-1c illustrate a first semiconductor wafer with a plurality of first semiconductor die separated by a saw street;

FIGS. 2a-2b illustrate a second semiconductor wafer with a plurality of second semiconductor die separated by a saw street;

FIGS. 3a-3c illustrate disposing the first semiconductor die and a plurality of conductive posts on the second semiconductor wafer;

FIGS. 4a-4g illustrate disposing a singulated second semiconductor die on an interconnect substrate with a dam wall to protect the sensitive area;

FIGS. 5a-5b illustrate a first embodiment of the dam wall;

FIGS. 6a-6b illustrate a second embodiment of the dam wall;

FIGS. 7a-7b illustrate a third embodiment of the dam wall; and

FIG. 8 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

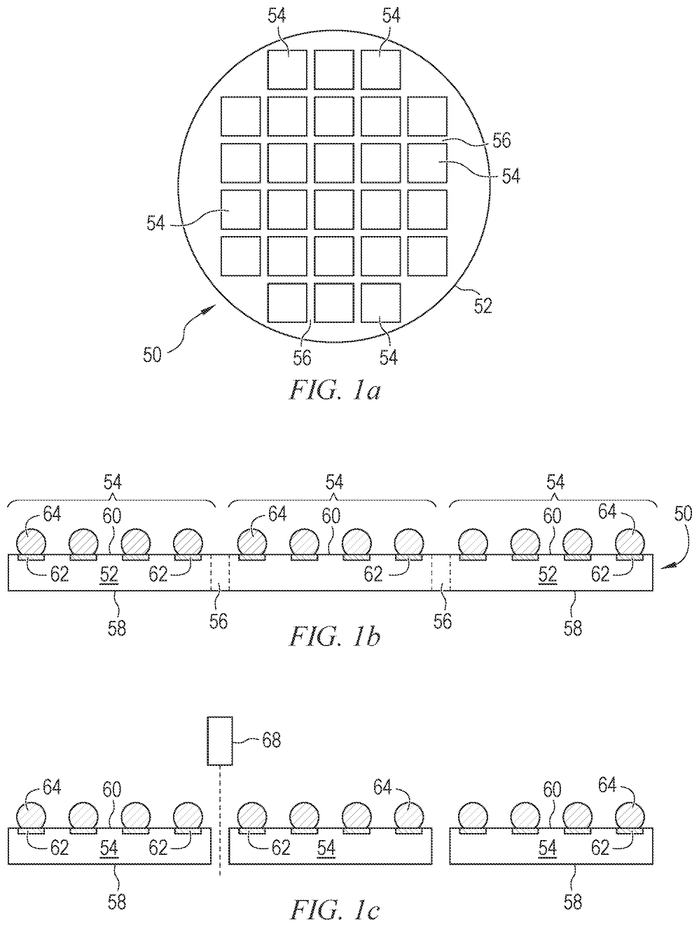

FIG. 1a shows a semiconductor wafer 50 with a base substrate material 52, such as silicon, germanium, aluminum phosphide, aluminum arsenide, gallium arsenide, gallium nitride, indium phosphide, silicon carbide, or other bulk material for structural support. A plurality of semiconductor die or components 52 is formed on wafer 50 separated by a non-active, inter-die wafer area or saw street 56. Saw street 56 provides cutting areas to singulate semiconductor wafer 50 into individual semiconductor die 54. In one embodiment, semiconductor wafer 50 has a width or diameter of 100-450 millimeters (mm).

FIG. 1B shows a cross-sectional view of a portion of semiconductor wafer 50. Each semiconductor die 54 has a back or non-active surface 58 and an active surface 60 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 60 to implement analog circuits or digital circuits, such as digital signal processor (DSP), application specific integrated circuits (ASIC), memory, or other signal processing circuit.

Semiconductor die 54 may also contain IPDs, such as inductors, capacitors, and resistors, for RF signal processing.

An electrically conductive layer 62 is formed over active surface 60 using PVD, CVD, electrolytic plating, electroless plating process, or other suitable metal deposition process. Conductive layer 62 can be one or more layers of aluminum (Al), copper (Cu), tin (Sn), nickel (Ni), gold (Au), silver (Ag), or other suitable electrically conductive material. Conductive layer 62 operates as contact pads electrically connected to the circuits on active surface 60.

An electrically conductive bump material is deposited over conductive layer 62 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 62 using a suitable attachment or bonding process. In one embodiment, the bump material is reflowed by heating the material above its melting point to form balls or bumps 64. In one embodiment, bump 64 is formed over an under bump metallization (UBM) having a wetting layer, barrier layer, and adhesive layer. Bump 64 can also be compression bonded or thermocompression bonded to conductive layer 62. Bump 64 represents one type of interconnect structure that can be formed over conductive layer 62. The interconnect structure can also use bond wires, conductive paste, stud bump, micro bump, or other electrical interconnect.

In FIG. 1c, semiconductor wafer 50 is singulated through saw street 56 using a saw blade or laser cutting tool 68 into individual semiconductor die 54. The individual semiconductor die 54 can be inspected and electrically tested for identification of known good die or unit (KGD/KGU) post singulation.

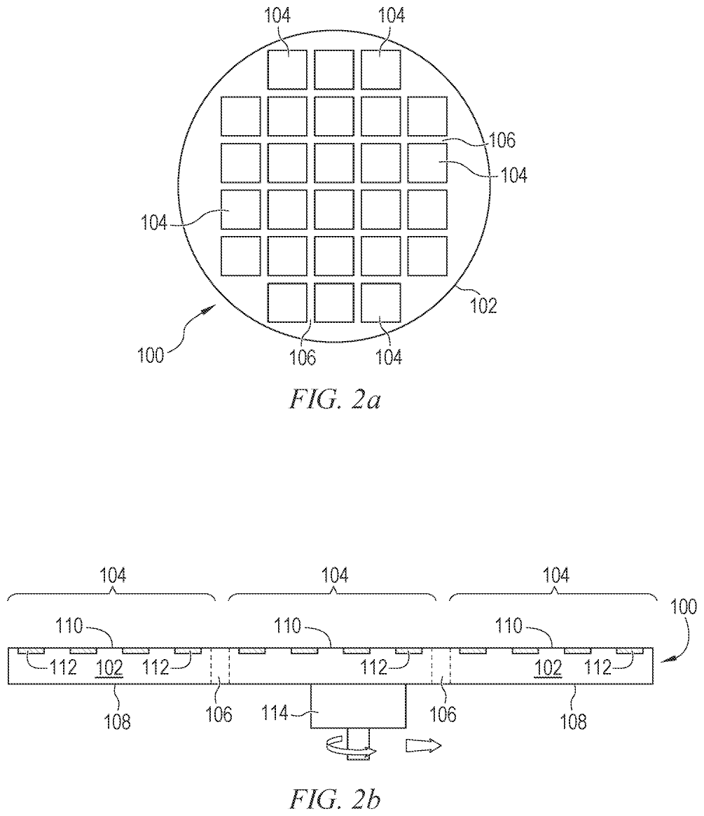

FIG. 2a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 mm.

FIG. 2b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as DSP, ASIC, memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of Al, Cu, Sn, Ni, Au, Ag, or other suitable electrically conductive material. Conductive layer 112 operates as contact pads electrically connected to the circuits on active surface 110. Back surface 108 can undergo a grinding operation with grinder 114 to planarize the surface.

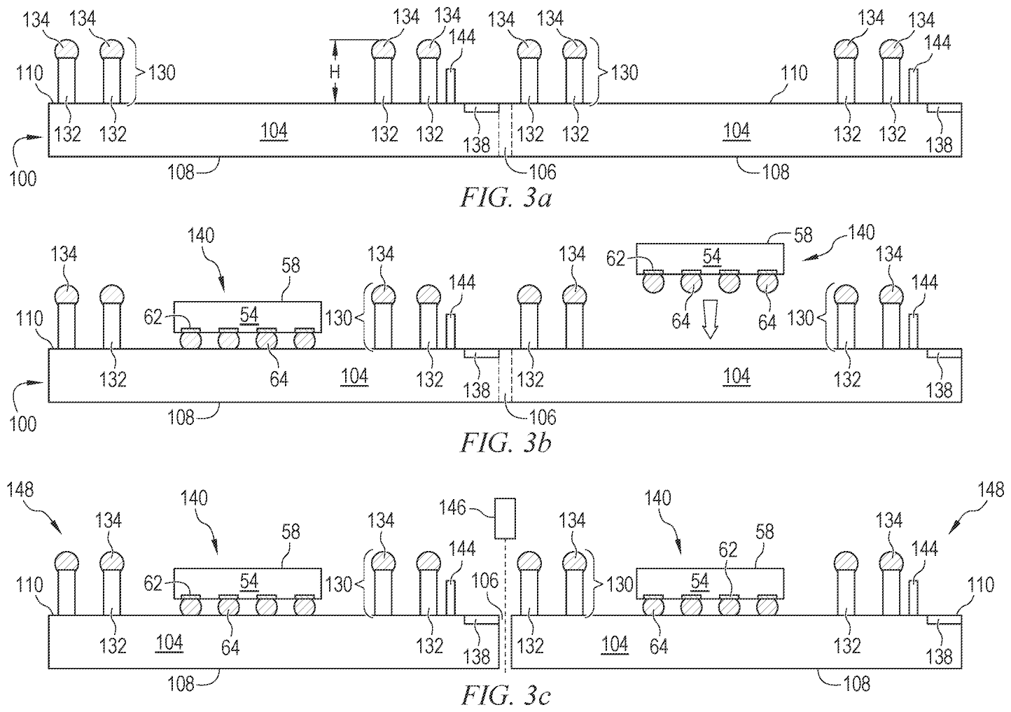

In FIG. 3a, a plurality of conductive pillars or posts 130 are formed on conductive layer 112 of semiconductor wafer 100. Each conductive post 130 has a vertical shaft 132 and bump 134 formed on a distal end of the vertical shaft. A solder resist can be formed over surface 110. The solder resist is etched to form vias for the locations of conductive posts 130. The vias are filled with conductive material and the solder resist is removed leaving vertical shaft 132. Bumps 134 are then formed on the distal end of vertical shafts 132. Vertical shafts 132 can be Al, Cu, Sn, Ni, Au, Ag, or other suitable electrically conductive material. The bump material can be Al, Sn, Ni, Au, Ag, Pb, Bi, Cu, solder, and combinations thereof, with an optional flux solution. In one embodiment, conductive post 130 has a height H of 60-140 μm.

Each semiconductor die 104 has a sensitive area 138 formed in active surface 110. In one embodiment, sensitive area 138 is a waveguide. Sensitive area 138 can be a sensor, optical, photonic region, or other feature of semiconductor die 104, generally at a perimeter of the die, that should be protected from foreign material or other contamination. In some cases, such as a waveguide, sensitive area 138 extends to the edge of semiconductor die 104 to continue to an adjacent die or other device.

Dam wall or fence 144 is formed over active surface 110 of semiconductor wafer 100 proximate to sensitive area 138. In one embodiment, dam wall 144 is formed between conductive posts 130 and dam wall 144. Dam wall 144 includes various segments of rigid material of sufficient structural strength to withstand the flow of underfill material, preferably formed at the same time and same material as conductive posts 130. Dam wall 144 will be used to block or inhibit later-applied underfill material from reaching sensitive area 138.

In FIG. 3b, a plurality of electrical components 140 is disposed on active surface 110 of semiconductor wafer 100 and electrically and mechanically connected to conductive layer 112. Electrical components 140 are each positioned over wafer 100 using a pick and place operation. For example, electrical component 140 can be similar to semiconductor die 54 from FIG. 1c with active surface 60 and bumps 64 oriented toward surface 110 of semiconductor wafer 100. Electrical component 140 can be discrete electrical devices, or IPDs, such as a diode, transistor, resistor, capacitor, and inductor. Alternatively, electrical component 140 can include other semiconductor die, semiconductor packages, surface mount devices, discrete electrical devices, or IPDs.

Electrical components 140 are brought into contact with surface 110 of wafer 100. FIG. 3c illustrates electrical components 140 electrically and mechanically connected to conductive layers 112 of wafer 100. Electrical component 140 disposed on semiconductor wafer 100 is a C2 W device.

Semiconductor wafer 100 is singulated through saw street 106 using a saw blade or laser cutting tool 146 into individual semiconductor die 104 each with additional semiconductor die 54 and conductive posts 130 disposed on active surface 110. The individual semiconductor die 104, with conductive posts 130 and electrical component 140, can be inspected and electrically tested for identification of KGD/KGU post singulation.

The combination of semiconductor die 104, semiconductor die 54, conductive posts 130, dam wall 144, and sensitive area 138 constitute C2 W semiconductor package 148.

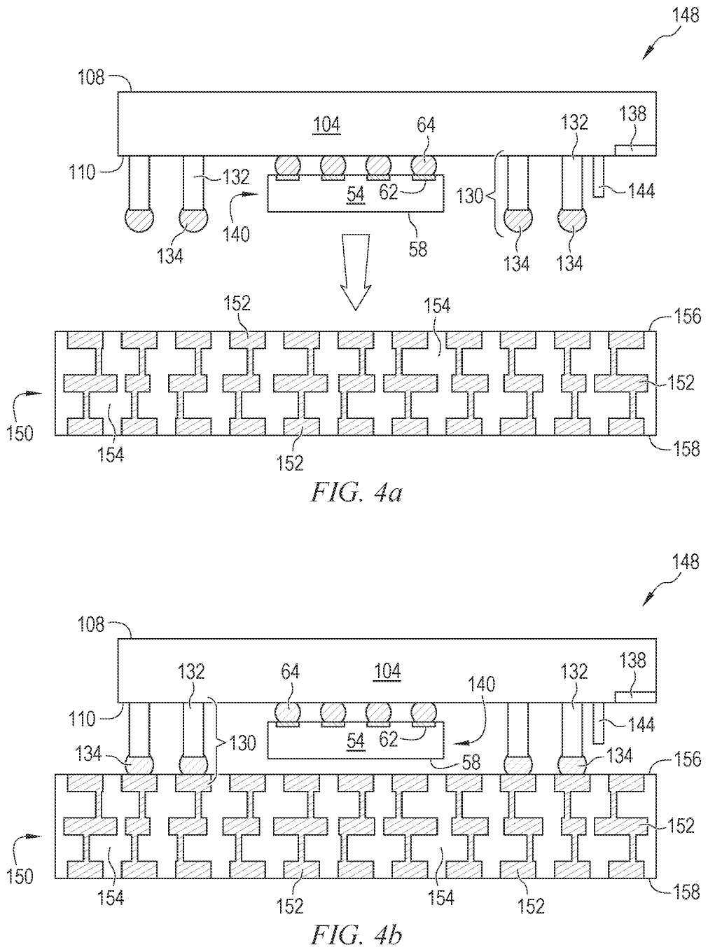

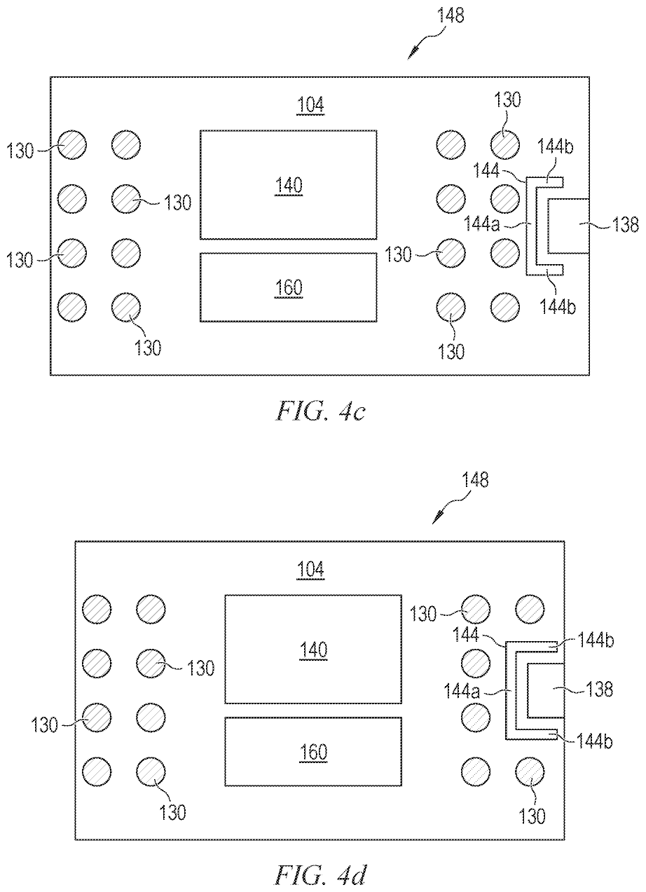

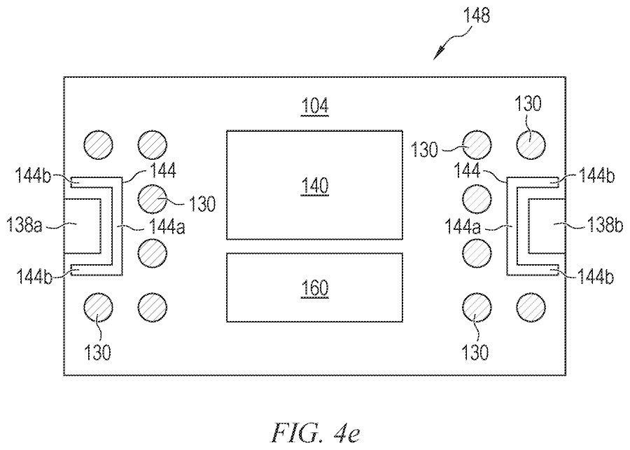

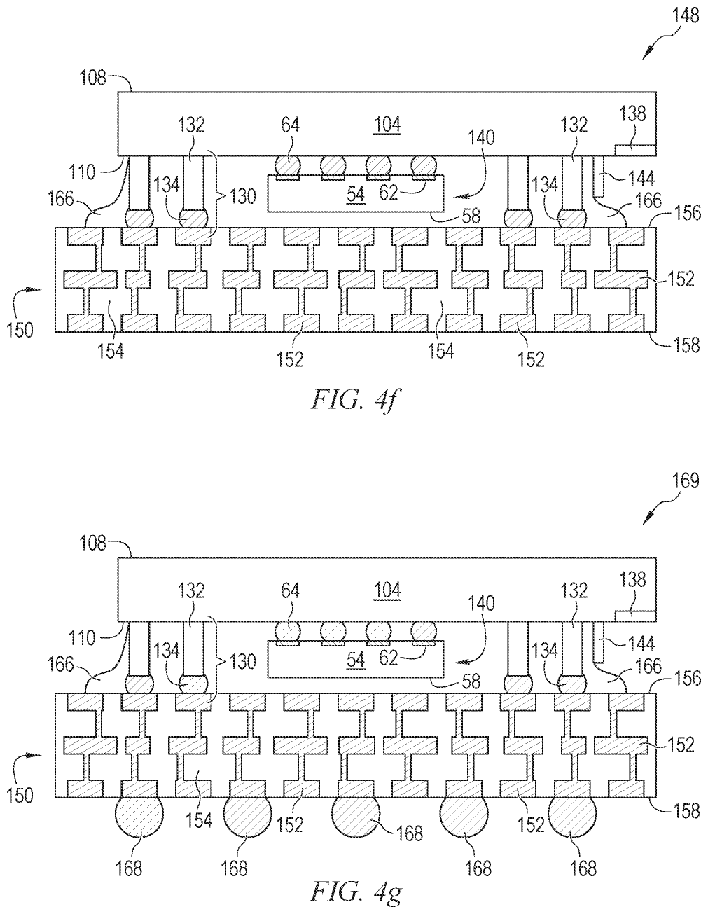

FIG. 4a shows a cross-sectional view of interconnect substrate 150 including conductive layers 152 and insulating layer 154. Conductive layer 152 can be one or more layers of Al, Cu, Sn, Ni, Au, Ag, or other suitable electrically conductive material. Conductive layers can be formed using PVD, CVD, electrolytic plating, electroless plating process, or other suitable metal deposition process. Conductive layer 152 provides horizontal electrical interconnect across substrate 150 and vertical electrical interconnect between top surface 156 and bottom surface 158 of substrate 150. Portions of conductive layer 152 can be electrically common or electrically isolated depending on the design and function of semiconductor die 104 and other electrical components. Insulating layer 154 contains one or more layers of SiO2, Si3N4, SiON, Ta2O5, Al2O3, solder resist, polyimide, BCB, PBO, and other material having similar insulating and structural properties. Insulating layers can be formed using PVD, CVD, printing, lamination, spin coating, spray coating, sintering or thermal oxidation. Insulating layer 154 provides isolation between conductive layers 152.

Semiconductor package 148 from FIG. 3c is positioned over surface 156 of interconnect substrate 150 with conductive posts 130 oriented toward the substrate. Semiconductor package 148 is brought into contact with surface 156 of interconnect substrate 150. FIG. 4b shows semiconductor package 148 disposed on interconnect substrate 150 with conductive posts 130 electrically and mechanically connected to conductive layer 152 on surface 156.

FIG. 4c is a bottom view of semiconductor package 148. An additional electrical component 160 can be disposed on active surface 110 of semiconductor die 104 as in FIGS. 3b-3c. Electrical component 160 can be similar to semiconductor die 54 from FIG. 1c, although with a different form and function, with active surface 60 and bumps 64 oriented toward surface 110 of semiconductor die 104. Semiconductor package 148 shows two rows of conductive posts 130 on each side of electrical components 140 and 160. Dam wall 144 is disposed between conductive posts 130 and sensitive area 138, in proximity to the sensitive area. Dam wall 144 is shown to have main wall 144a and side wings 144b.

FIG. 4d is a bottom view of another embodiment of semiconductor package 148. Electrical component 160 is disposed on active surface 110 of semiconductor die 104. Electrical component 160 can be similar to semiconductor die 54 from FIG. 1c, although with a different form and function, with active surface 60 and bumps 64 oriented toward active surface 110 of semiconductor die 104. In this case, dam wall 144 is placed within one row of conductive posts 130, proximate to sensitive area 138. Dam wall 144 is shown to have main wall 144a and side wings 144b.

FIG. 4e is a bottom view of another embodiment of semiconductor package 148. Electrical component 160 is disposed on active surface 110 of semiconductor die 104. Electrical component 160 can be similar to semiconductor die 54 from FIG. 1c, although with a different form and function, with active surface 60 and bumps 64 oriented toward surface 110 of semiconductor die 104. In this case, semiconductor die 104 has two sensitive areas 138a and 138b with respective dam walls 144a and 144b each placed within one row of conductive posts 130, proximate to sensitive area 138.

In FIG. 4f, underfill material 166, such as epoxy resin, is deposited under semiconductor die 104 and around conductive posts 130 and electrical components 140 and 160. Underfill material 166 isolates and protects active surfaces of electrical components 140 and 160, active surface 110 of semiconductor die 104, and conductive posts 130. However, dam wall 144 blocks or inhibits underfill material 166 from reaching sensitive area 138. Dam wall 144 protects sensitive area 138 from being contaminated or covered by underfill material 166.

In FIG. 4g, an electrically conductive bump material is deposited over conductive layer 152 on surface 158 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 152 using a suitable attachment or bonding process. In one embodiment, the bump material is reflowed by heating the material above its melting point to form balls or bumps 168. In one embodiment, bump 168 is formed over a UBM having a wetting layer, barrier layer, and adhesive layer. Bump 168 can also be compression bonded or thermocompression bonded to conductive layer 152. In one embodiment, bump 168 is a copper core bump for durability and maintaining its height. Bump 168 represents one type of interconnect structure that can be formed over conductive layer 152. The interconnect structure can also use bond wires, conductive paste, stud bump, micro bump, or other electrical interconnect.

The combination of semiconductor die 104, semiconductor die 54, conductive posts 130, dam wall 144, sensitive area 138, interconnect substrate 150, and underfill material 166 constitute C2 W semiconductor package 169.

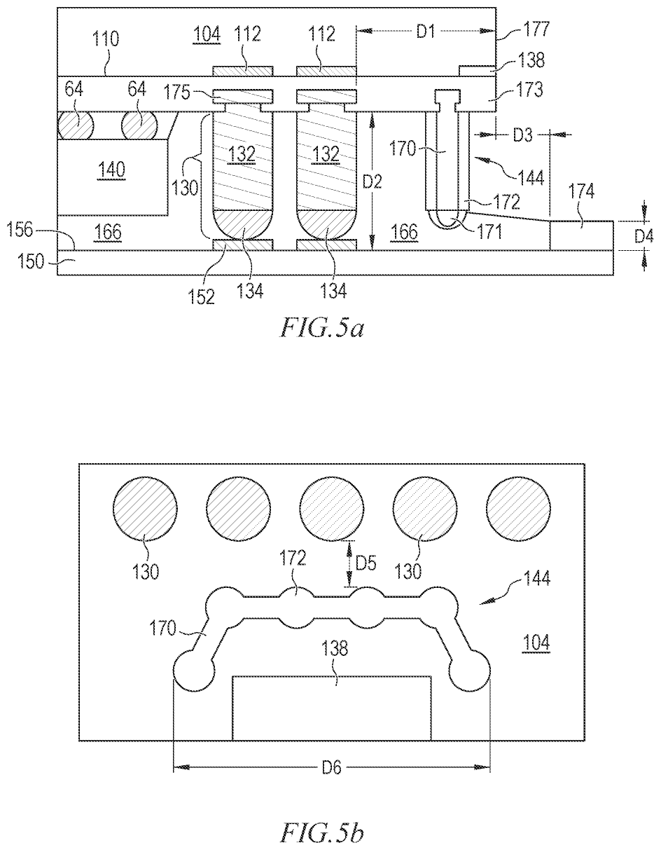

FIGS. 5a-5b illustrate further detail of dam wall 144. FIG. 5a is a cross-sectional view showing details of dam wall 144. FIG. 5b is a bottom view showing details of dam wall 144. In one embodiment, dam wall 144 includes a plurality of segments of rigid material, having varying or different widths, of sufficient structural strength to withstand the flow of underfill material. Vertical segment 170 has a first width and rounded segment 172 has a second width greater than the first width of the vertical segment. Vertical segments 170 are integrated with alternating rounded segments as a unitary body. Segments 170-172 can be made of one or more layers of Al, Cu, Sn, Ni, Au, Ag, or other suitable material with sufficient rigidity and structural strength to withstand the flow of underfill material. Alternatively, segments 170-172 can be made of multi-layer flexible laminate, ceramic, copper clad laminate (CCL), glass, polymer, epoxy molding compound, one or more laminated layers of polytetrafluoroethylene (PTFE) pre-impregnated (prepreg), FR-4, FR-1, CEM-1, or CEM-3 with a combination of phenolic cotton paper, epoxy, resin, woven glass, matte glass, polyester, and other reinforcement fibers or fabrics, SiO2, Si3N4, SiON, Ta2O5, Al2O3, solder resist, polyimide, BCB, PBO and other material having similar insulating and structural properties suitable to withstanding the flow of underfill material. In one embodiment, segments 170-172 are Cu, formed at the same time as conductive posts 130.

Tips 171 of segments 170-172 terminate before reaching surface 156 of substrate 150, leaving a gap between dam wall 144 and surface 156 of substrate 150, to allow underfill material to flow under and around the dam wall. FIG. 5a shows further detail of semiconductor die 104, including insulating layer 173 and conductive layer 175 formed over active surface 110 of semiconductor die 104. Conductive layer 175 is part of a redistribution layer (RDL) electrically connected to conductive posts 130, as well as conductive layer 112. Insulating layer 173 provides isolation for conductive layer 175. Sensitive area 138 extends to side surface 177 of semiconductor die 104. In the case of a waveguide, sensitive area 138 would connect with an adjacent die or other device. Dam wall 144 may have a similar height as conductive posts 130.

An insulating layer 174, such as solder resist, is formed over surface 156, outside dam wall 144 and outside a footprint of semiconductor die 104. In one embodiment, the distance from the edge of semiconductor die 104 to the outermost conductive post is D1=534 micrometers (μm). The distance from semiconductor die 104 to interconnect substrate 150 is D2=120 μm. The distance from semiconductor die 104 to insulating layer 174 is D3= at least 100 μm. The thickness of insulating layer 174 is D4=10-15 μm. The distance from conductive posts 130 to dam wall 144 is D5=50 μm. The length of dam wall 144 is at least D6=6.0 mm.

Underfill material 166 flows from left to right. Upon reaching dam wall 144, underfill material flows under and around segments 170-172, with the flow held back by insulating layer 174. Dam wall 144 provides sufficient rigidity and structural strength to cause underfill material 166 to flow under and around the dam structure. Underfill material 166 does not reach sensitive area 138 on side surface 177 by nature of segments 170-172 of dam wall 144 and insulating layer 174 inhibiting the flow of the underfill material. Sensitive area 138 and substantially all of side surface 177 remains free of underfill material 166.

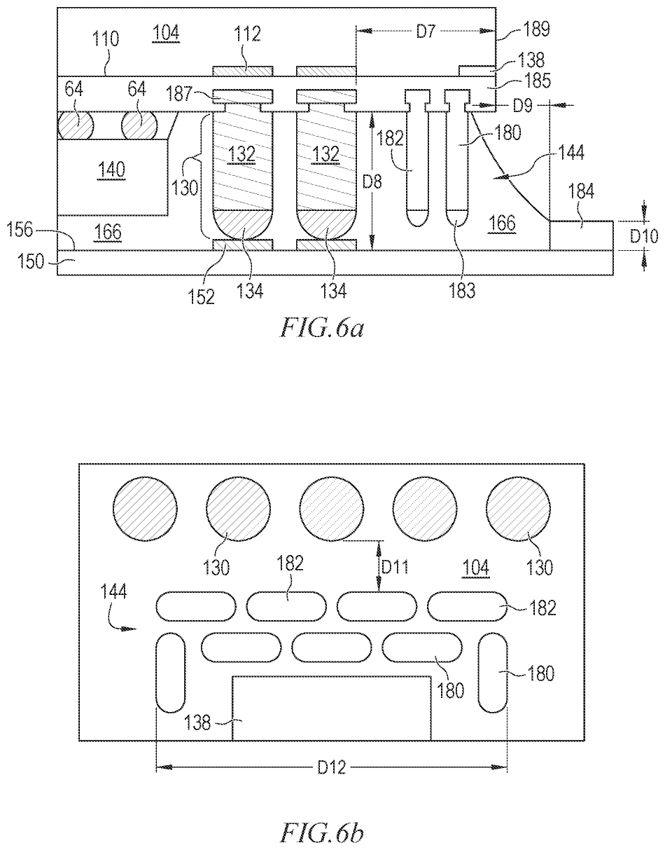

FIGS. 6a-6b illustrate an alternate embodiment of dam wall 144. FIG. 6a is a cross-sectional view showing details of dam wall 144. FIG. 6b is a bottom view showing details of dam wall 144. In one embodiment, dam wall 144 includes a plurality of physically separate vertical segments of rigid material of sufficient structural strength to withstand the flow of underfill material. Separate vertical segments 180 form a first row of dam wall 144 and side wings. Separate vertical segments 182 forms a second row of dam wall 144. Note that vertical segments 182 overlap gaps between the first row of vertical segments 180. For example, one vertical segment 182 is placed in the gap between adjacent and separate vertical segments 180. Dam wall 144 can have any number of overlapping rows of separate vertical segments. Separate vertical segments 180-182 can be made of one or more layers of Al, Cu, Sn, Ni, Au, Ag, or other suitable material with sufficient rigidity and structural strength to withstand the flow of underfill material. Alternatively, vertical segments 180-182 can be made of multi-layer flexible laminate, ceramic, CCL, glass, polymer, epoxy molding compound, one or more laminated layers of PTFE prepreg, FR-4, FR-1, CEM-1, or CEM-3 with a combination of phenolic cotton paper, epoxy, resin, woven glass, matte glass, polyester, and other reinforcement fibers or fabrics, SiO2, Si3N4, SiON, Ta2O5, Al2O3, solder resist, polyimide, BCB, PBO and other material having similar insulating and structural properties suitable to withstanding the flow of underfill material. In one embodiment, separate vertical segments 180-182 are Cu, formed at the same time as conductive posts 130.

Tips 183 of separate vertical segments 180-182 terminate before reaching surface 156 of substrate 150, leaving a gap between dam wall 144 and surface 156 of substrate 150, to allow underfill material to flow under and around dam wall 144. FIG. 6a shows further detail of semiconductor die 104, including insulating layer 185 and conductive layer 187 formed over active surface 110 of semiconductor die 104. Conductive layer 187 is part of a RDL electrically connected to conductive posts 130, as well as conductive layer 112. Insulating layer 185 provides isolation for conductive layer 187. Sensitive area 138 extends to side surface 189 of semiconductor die 104. In the case of a waveguide, sensitive area 138 would connect with an adjacent die or other device.

An insulating layer 184, such as solder resist, is formed over surface 156, outside dam wall 144 and outside a footprint of semiconductor die 104. In one embodiment, the distance from the edge of semiconductor die 104 to the outermost conductive post is D7=534 μm. The distance from semiconductor die 104 to interconnect substrate 150 is D8=120 μm. The distance from semiconductor die 104 to insulating layer 184 is D9= at least 100 μm. The thickness of insulating layer 184 is D10=10-15 μm. The distance from conductive posts 130 to dam wall 144 is D11=50 μm. The length of dam wall 144 is at least D12=6.0 mm.

Underfill material 166 flows from left to right. Upon reaching dam wall 144, underfill material flows under and around separate vertical segments 180-182, with the flow held back by insulating layer 184. Dam wall 144 provides sufficient rigidity and structural strength to cause underfill material 166 to flow under and around the dam structure. Underfill material 166 does not reach sensitive area 138 on side surface 189 by nature of separate vertical segments 180-182 of dam wall 144 and insulating layer 184 inhibiting the flow of the underfill material. Sensitive area 138 and substantially all of side surface 189 remains free of underfill material 166.

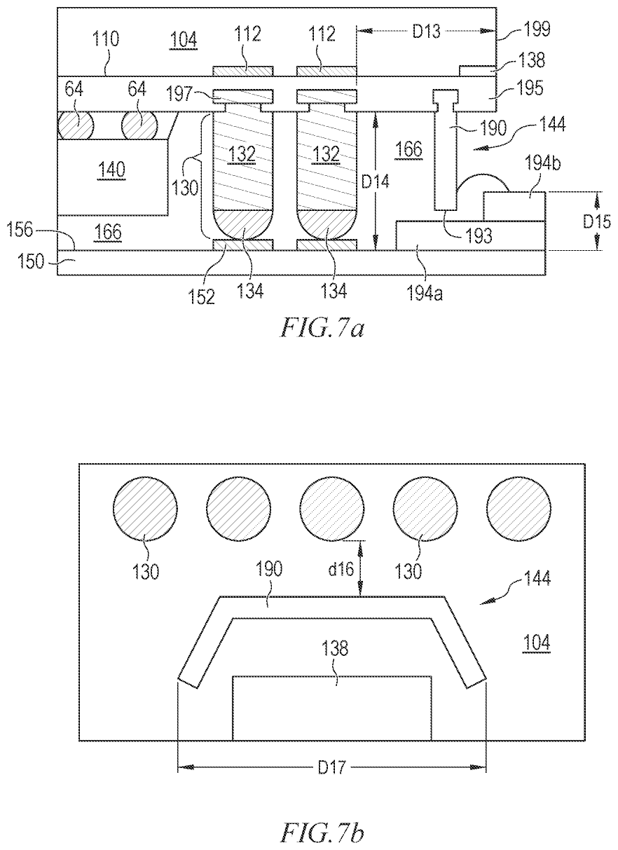

FIGS. 7a-7b illustrate another alternate embodiment of dam wall 144. FIG. 7a is a cross-sectional view showing details of dam wall 144. FIG. 7b is a bottom view showing details of dam wall 144. In one embodiment, dam wall 144 includes a plurality of vertical segments of sufficient rigidity and structural strength to withstand the flow of underfill material. Vertical segments 190 can be made of one or more layers of Al, Cu, Sn, Ni, Au, Ag, or other suitable material with sufficient rigidity and structural strength to withstand the flow of underfill material. Alternatively, vertical segments 190 can be made of multi-layer flexible laminate, ceramic, CCL, glass, polymer, epoxy molding compound, one or more laminated layers of PTFE prepreg, FR-4, FR-1, CEM-1, or CEM-3 with a combination of phenolic cotton paper, epoxy, resin, woven glass, matte glass, polyester, and other reinforcement fibers or fabrics, SiO2, Si3N4, SiON, Ta2O5, Al2O3, solder resist, polyimide, BCB, PBO and other material having similar insulating and structural properties suitable to withstanding the flow of underfill material. In one embodiment, vertical segments 190 are Cu, formed at the same time as conductive posts 130.

Tips 193 of vertical segments 190 terminate before reaching surface 156 of substrate 150, leaving a gap between dam wall 144 and surface 156 of substrate 150, to allow underfill material to flow under and around dam wall 144. FIG. 7a shows further detail of semiconductor die 104, including insulating layer 195 and conductive layer 197 formed over active surface 110 of semiconductor die 104. Conductive layer 197 is part of a RDL electrically connected to conductive posts 130, as well as conductive layer 112. Insulating layer 195 provides isolation for conductive layer 197. Sensitive area 138 extends to side surface 199 of semiconductor die 104. In the case of a waveguide, sensitive area 138 would connect with an adjacent die or other device.

A first insulating layer 194a, such as solder resist, is formed over surface 156, outside dam wall 144. A second insulating layer 194b, such as solder resist, is formed over first insulating layer 194a. In one embodiment, the distance from the edge of semiconductor die 104 to the outermost conductive post is D13=534 μm. The distance from semiconductor die 104 to interconnect substrate 150 is D14=120 μm. The thickness of insulating layers 194a and 194b is D15=25-30 μm. The distance from conductive posts 130 to dam wall 144 is D16=50 μm. The length of dam wall 144 is at least D17=6.0 mm.

Underfill material 166 flows from left to right. Upon reaching dam wall 144, underfill material flows under and around vertical segments 190, with the flow held back by insulating layers 194a-194b. Dam wall 144 provides sufficient rigidity and structural strength to cause underfill material 166 to flow under and around the dam structure. Underfill material 166 does not reach sensitive area 138 on side surface 199 by nature of vertical segments 190 of dam wall 144 and insulating layers 194a-194b inhibiting the flow of the underfill material. Sensitive area 138 and substantially all of side surface 199 remains free of underfill material 166.

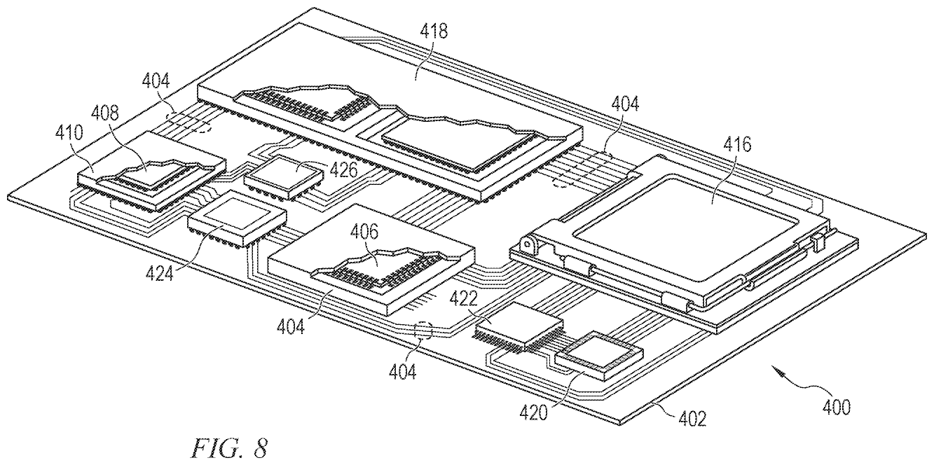

FIG. 8 illustrates electronic device 400 having a chip carrier substrate or PCB 402 with a plurality of semiconductor packages disposed on a surface of PCB 402, including semiconductor package 169. Electronic device 400 can have one type of semiconductor package, or multiple types of semiconductor packages, depending on the application.

Electronic device 400 can be a stand-alone system that uses the semiconductor packages to perform one or more electrical functions. Alternatively, electronic device 400 can be a subcomponent of a larger system. For example, electronic device 400 can be part of a tablet, cellular phone, digital camera, communication system, or other electronic device. Alternatively, electronic device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 8, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electronic components, can be connected to PCB 402. In some embodiments, electronic device 400 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor die including a sensitive area;
forming a dam wall over the semiconductor die proximate to the sensitive area;
disposing an electrical component over the semiconductor die;
providing a substrate;
disposing the semiconductor die and electrical component over the substrate; and
depositing an underfill material between the semiconductor die and substrate, wherein the dam wall inhibits the underfill material from contacting any portion of the sensitive area.

2. The method of claim 1, further including forming a plurality of conductive posts over the semiconductor die.

3. The method of claim 1, wherein forming the dam wall includes providing a vertical segment and side wings.

4. The method of claim 1, wherein forming the dam wall includes forming a plurality of rounded segments integrated with a plurality of vertical segments as a unitary body.

5. The method of claim 1, wherein forming the dam wall includes forming a plurality of separate vertical segments.

6. The method of claim 1, further including forming an insulating layer over the substrate outside the dam wall.

7. A method of making a semiconductor device, comprising:
providing a semiconductor die including a sensitive area;
forming a dam wall over the semiconductor die proximate to the sensitive area; and
depositing an underfill material over the semiconductor die, wherein the dam wall inhibits the underfill material from contacting the sensitive area.

8. The method of claim 7, further including:
forming a disposing an electrical component over the semiconductor die;
providing a substrate; and
disposing the semiconductor die and electrical component over the substrate.

9. The method of claim 8, further including forming an insulating layer over the substrate outside the dam wall.

10. The method of claim 7, further including forming a plurality of conductive posts over the semiconductor die.

11. The method of claim 7, wherein forming the dam wall includes forming a vertical segment and side wings.

12. The method of claim 7, wherein forming the dam wall includes forming a plurality of rounded segments integrated with a plurality of vertical segments as a unitary body.

13. The method of claim 7, wherein forming the dam wall includes forming a plurality of separate vertical segments.

14. A semiconductor device, comprising:
a semiconductor die including a sensitive area;
a dam wall formed over the semiconductor die proximate to the sensitive area;
an electrical component disposed over the semiconductor die;
a substrate, wherein the semiconductor die and electrical component are disposed over the substrate; and
an underfill material deposited between the semiconductor die and substrate, wherein the dam wall inhibits the underfill material from contacting the sensitive area.

15. The semiconductor device of claim 14, further including a plurality of conductive posts formed over the semiconductor die.

16. The semiconductor device of claim 14, wherein the dam wall includes a vertical segment and side wings.

17. The semiconductor device of claim 14, wherein the dam wall includes a plurality of rounded segments integrated with a plurality of vertical segments as a unitary body.

18. The semiconductor device of claim 14, wherein the dam wall includes a plurality of separate vertical segments.

19. The semiconductor device of claim 14, further including an insulating layer formed over the substrate outside the dam wall.

20. A semiconductor device, comprising:
a semiconductor die including a sensitive area;
a dam wall formed over the semiconductor die proximate to the sensitive area; and
an underfill material deposited over the semiconductor die, wherein the dam wall inhibits the underfill material from contacting the sensitive area.

21. The semiconductor device of claim 20, further including:
an electrical component disposed over the semiconductor die;
a substrate, wherein the semiconductor die and electrical component are disposed over the substrate.

22. The semiconductor device of claim 20, further including a plurality of conductive posts formed over the semiconductor die.

23. The semiconductor device of claim 20, wherein the dam wall includes a vertical segment and side wings.

24. The semiconductor device of claim 20, wherein the dam wall includes a plurality of rounded segments integrated with a plurality of vertical segments as a unitary body.

25. The semiconductor device of claim 20, wherein the dam wall includes a plurality of separate vertical segments.
